(19) United States
(12) Patent Application Publication
(10) Pub. No.: US 2017/0324006 A1
(43) Pub. Date: Nov. 9, 2017

(54) METHOD OF PRODUCING A CARRIER AND METHOD OF PRODUCING AN OPTOELECTRONIC COMPONENT

(71) Applicant: OSRAM Optl Semiconductors GmbH, Regensburg (DE)

(72) Inventor: Tobias Gebuhr, Regensburg (DE)

(21) Appl. No.: 15/525,404

(22) PCT Filed: Nov. 10, 2015
(86) PCT No.: PCT/EP2015/076159

§ 371 Date: May 9, 2017

(30) Foreign Application Priority Data
Nov. 10, 2014 (DE) 10 2014 116 370.2

(51) Int. Cl. H01L 33/48; H01L 33/62; H01L 23/00; H01L 33/60

(52) U.S. Cl. CPC H01L 33/486; H01L 33/60; H01L 33/62; H01L 24/48; H01L 2224/48091; H01L 2924/12041; H01L 2933/0033; H01L 2933/0066; H01L 2224/48247

(57) ABSTRACT

A method of producing a carrier for an optoelectronic component includes providing a lead frame having an upper side and a lower side; arranging a first film on the lower side of the lead frame; arranging a second film on the upper side of the lead frame; forming a molded body from a molding material, the lead frame being embedded in the molded body; and removing the first film and the second film.

### TECHNICAL FIELD

This disclosure relates to a method of producing a carrier for an optoelectronic component and a method of producing an optoelectronic component.

### BACKGROUND

Optoelectronic components, for example, light-emitting diode components having housings based on lead frames are known. To produce such optoelectronic components, a lead frame is embedded in a molded body. In this case, undesired covering of contact pads of the lead frame by the molding material of the molded body generally takes place, which necessitates subsequent cleaning.

### SUMMARY

I provide a method of producing a carrier for an optoelectronic component including providing a lead frame having an upper side and a lower side; arranging a first film on the lower side of the lead frame; arranging a second film on the upper side of the lead frame; forming a molded body from a molding material, the lead frame being embedded in the molded body; and removing the first film and the second film.

I also provide a method of producing an optoelectronic component including producing a carrier for an optoelectronic component including providing a lead frame having an upper side and a lower side; arranging a first film on the lower side of the lead frame; arranging a second film on the upper side of the lead frame; forming a molded body from a molding material, the lead frame being embedded in the molded body; and removing the first film and the second film; and arranging an optoelectronic semiconductor chip on an upper side of the carrier.

### BRIEF DESCRIPTION OF THE DRAWINGS

FIG. 1 schematically shows a perspective view of a lead frame.

FIG. 2 schematically shows a view of the lead frame with a first film arranged on a lower side.

FIG. 3 schematically shows the lead frame with a second film arranged on an upper side.

FIG. 4 schematically shows a molded body, which is formed between the film and in which the lead frame is embedded.

FIG. 5 schematically shows a perspective view of the molded body after the removal of the films.

FIG. 6 schematically shows a perspective view of an optoelectronic component produced from a molded body section of the molded body.

### LIST OF REFERENCES

10 optoelectronic component
100 lead frame
101 upper side
102 lower side
110 first lead frame section
120 second lead frame section
200 first film
201 first side
202 second side
300 second film
301 first side
302 second side
310 uncovered section
400 molded body
401 upper side
402 lower side
410 molded body section
500 carrier
501 upper side
502 lower side
600 optoelectronic semiconductor chip
601 upper side
602 lower side
610 bonding wire

### DETAILED DESCRIPTION

I provide a method of producing a carrier for an optoelectronic component comprising providing a lead frame having an upper side and a lower side, arranging a first film on the lower side of the lead frame, arranging a second film on the upper side of the lead frame, forming a molded body from a molding material, the lead frame being embedded in the molded body, and removing the first film and the second film.

The films arranged on the lower and upper sides of the lead frame in this method can substantially prevent the lower and upper sides of the lead frame from being covered with the molding material during formation of the molded body. In this method, therefore, a subsequent cleaning step to remove the molding material from the lower side and/or the upper side of the lead frame is advantageously not necessary. This has the advantage that a mechanical and/or chemical load on the carrier, associated with cleaning of the upper side and/or the lower side of the carrier, is avoided in this method. The risk of cracking or other damage to the carrier is therefore reduced. In this way, the stability of the carrier obtainable by the method can be increased.

Omission of the cleaning step also avoids the risk of roughening the upper side and/or the lower side of the lead frame, which is associated with a reflectivity reduction so that the carrier obtainable by the method can have a high optical reflectivity. In this way, an optoelectronic component produced from the carrier can have an increased brightness.

Omission of the cleaning step also reduces the risk of damage to the molding material enclosing the lead frame. Such damage may be associated with accelerated ageing, reduced reflectivity and reduced mechanical stability.

Avoidance of a cleaning step subsequent to the formation of the molded body furthermore reduces the risk of creating scratches or other mechanical damage on the solder contact pads of the carrier. In this way, reliability of an optoelectronic component produced from the carrier can be increased.

Because of the omission of a cleaning step to remove the molding material covering the lower side and/or the upper side of the lead frame, the time taken to carry out the method and the costs of the method can furthermore advantageously be reduced.

The first film and/or the second film may be self-adhesive films. In this case, self-adhesive sides of the films may face toward the lower side and/or the upper side of the lead frame. Advantageously, the films therefore adhere to the lower side and/or the upper side of the lead frame so that particularly reliable protection of the lower side and/or the upper side of the lead frame from being covered by the molding material of the molded body is achieved. Owing to adhesive fastening of the first film and/or the second film to the lead frame, the lead frame with the films adhering thereto is furthermore particularly easy to handle so that the method can be carried out particularly simply.

The first film and/or the second film may comprise a polyimide, ETFE or PET. Advantageously, according to experience, such films are suitable for use in molding processes.

The molded body may be formed by a molding method, in particular by transfer molding. Advantageously, this allows the production method to be carried out economically and reproducibly.

The first film or the second film may be arranged such that a section of the lower side or the upper side of the lead frame remains uncovered by the film. In this case, the molding material is delivered between the first film and the second film at the uncovered section. Advantageously, reliable embedding of the entire lead frame in the molded body formed from the molding material can thereby be ensured.

The molding material may comprise an epoxy resin and/or a silicone. Advantageously, the molding material therefore has favorable mechanical properties and can be obtained economically.

The lead frame may comprise a multiplicity of first lead frame sections and a multiplicity of second lead frame sections. This makes it possible to produce a multiplicity of carriers for optoelectronic components from the lead frame. The method therefore allows economical mass production.

My method of producing an optoelectronic component comprises producing a carrier by a method of the type mentioned above, and arranging an optoelectronic semiconductor chip on an upper side of the carrier. This method makes it possible to produce an optoelectronic component with compact external dimensions. The method is in this case suitable for mass production so that the costs for production of an individual optoelectronic component are advantageously reduced. The carrier, produced by the method mentioned above, of the optoelectronic component obtainable by the method advantageously has a high mechanical quality.

The optoelectronic semiconductor chip may electrically conductively connect to a first lead frame section and a second lead frame section. The first lead frame section and the second lead frame section may thus be used in the optoelectronic component obtainable by the method to apply an electrical voltage and electrical current to the optoelectronic semiconductor chip of the optoelectronic component. At the same time, the first lead frame section and the second lead frame section may be used in the optoelectronic component obtainable by the method as electrical contact pads for electrical contacting of the optoelectronic component.

The optoelectronic semiconductor chip may be arranged on a first lead frame section. In this case, owing to the arrangement of the optoelectronic semiconductor chip on the first lead frame section, an electrically conductive connection may advantageously simultaneously be produced between the optoelectronic semiconductor chip and the first lead frame section. Advantageously, this leads to a particularly compact optoelectronic component obtainable by the method.

The method may comprise a further step of dividing the molded body to form a molded body section in which one of the first lead frame sections and one of the second lead frame sections are embedded. In this case, the optoelectronic semiconductor chip is arranged on the molded body section. The method therefore allows simultaneous production of a multiplicity of optoelectronic components in common processing steps. In this way, the costs of producing an optoelectronic component and the time taken to produce an optoelectronic component are advantageously reduced.

The above-described properties, features and advantages as well as the way in which they are achieved will become clear and more readily comprehensible in conjunction with the following description of examples which will be explained in more detail in connection with the drawings.

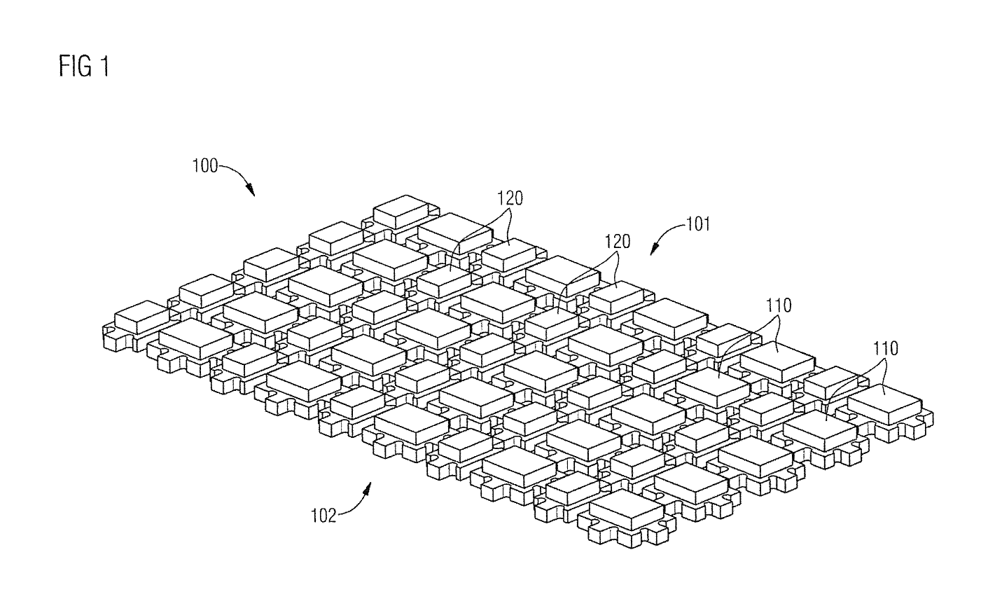

FIG. 1 shows a schematic perspective representation of a lead frame 100.

The lead frame 100 comprises an electrically conductive material, for example, a metal. The lead frame 100 preferably comprises copper. A coating to improve the solderability of the lead frame 100 may be arranged on the surfaces of the lead frame 100.

The lead frame 100 has an essentially flat and planar shape, with an upper side 101 and a lower side 102 lying opposite the upper side 101. The lead frame 100 may, for example, be produced from a metal sheet.

The lead frame 100 has openings extending through the lead frame 100 from the upper side 101 to the lower side 102, by which the lead frame 100 is subdivided into a multiplicity of first lead frame sections 110 and second lead frame sections 120. The openings may, for example, have been formed by an etching method. In addition to the openings, the lead frame 100 may have further recesses on its upper side 101 and/or on its lower side 102, which do not extend fully through the lead frame 100.

The first lead frame sections 110 and the second lead frame sections 120 are arranged in a regular grid arrangement in the plane of the lead frame 110. Each first lead frame section 110 and a neighboring second lead frame section 120 form an associated pair. In each such pair, the first lead frame section 110 and the associated second lead frame section 120 connect to one another not directly, but only via the respective further neighbors.

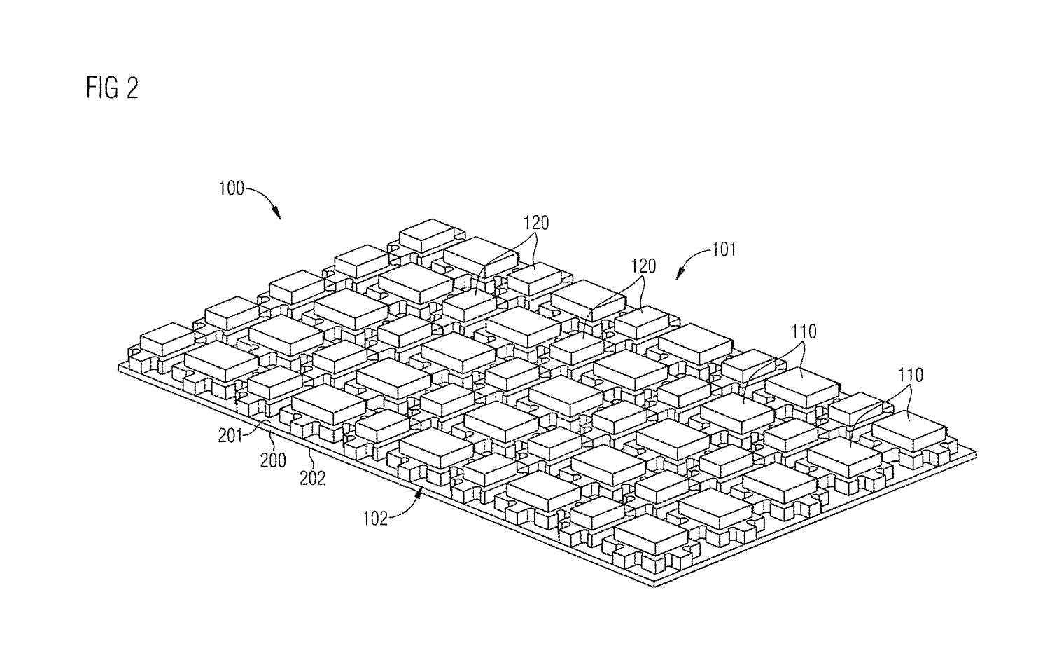

FIG. 2 shows a schematic perspective representation of the lead frame 100 in a processing state chronologically following the representation of FIG. 1.

A first film 200 has been arranged on the lower side 102 of the lead frame 100. The film 200 has a first side 201 and a second side 202 lying opposite the first side 201. The first side 201 of the first film 200 faces toward the lower side 102 of the lead frame 100 and covers the lower side 102 of the lead frame 100 preferably fully. If the lower side 102 of the lead frame 100 has elevated and depressed sections, then the first film 200 is in contact only with the elevated sections of the lower side 102.

The first film 200 may, for example, comprise a polyimide.

The first film 200 may be configured as a self-adhesive film. In this case, the first side 201 facing toward the lower side 102 of the lead frame 100 of the first film 200 is configured to be self-adhesive. The first side 201 of the first film 200 then adheres to the lower side 102 of the lead frame 100.

If the first film 200 is not configured as a self-adhesive film, then the first film 200 is preferably configured to be soft and pliable so that reliable covering of the entire lower side 102 of the lead frame 100 with the first film 200 can be ensured by pressing the lead frame 100 onto the first side 201 of the film 200.

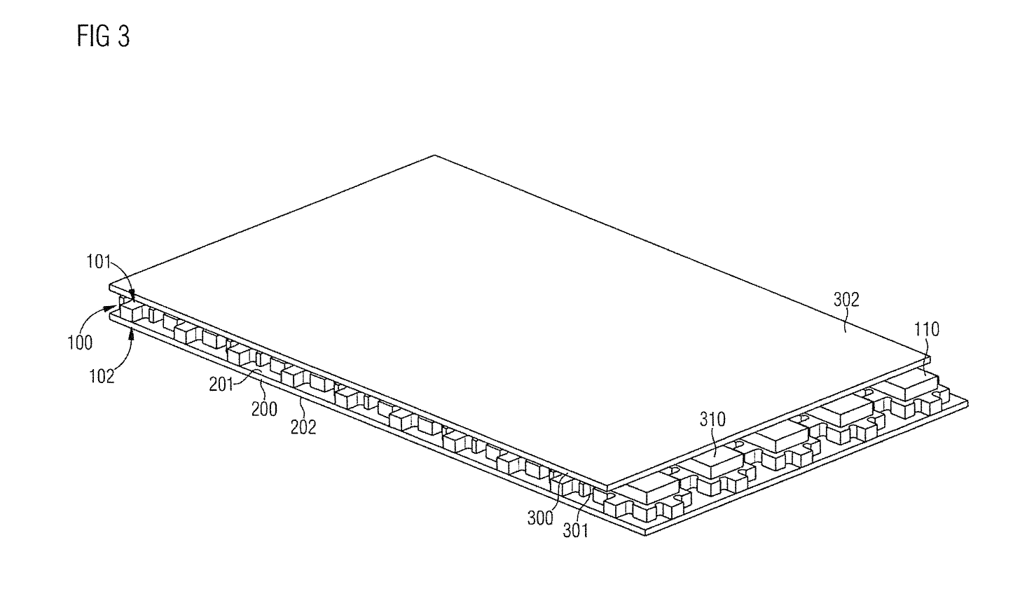

FIG. 3 shows a schematic perspective representation of the lead frame 100 in a processing state chronologically following the representation of FIG. 2.

A second film 300 has been arranged on the upper side 101 of the lead frame 100. The second film 300 has a first side 301 and a second side 302 lying opposite the first side 301. The first side 301 of the second film 300 faces toward the upper side 101 of the lead frame 100. The second film 300 covers a large part of the upper side 101 of the lead frame 100. If the upper side 101 of the lead frame 100 has elevated and depressed sections, then the second film 300 covers only the elevated sections of the upper side 101 of the lead frame 100.

The second film 300 preferably covers the upper side 101 of the lead frame 100 in all sections apart from an uncovered section 310, which remains uncovered by the second film 300. The uncovered section 310 is preferably arranged in an edge region of the lead frame 100. For example, the uncovered section 310 may extend along an edge of the lead frame 100. The uncovered section 310 may also be arranged in a corner region of the lead frame 100.

The second film 300 may be configured in the same way as the first film 200. The second film 300 may, for example, comprise a polyimide.

The second film 300 may be configured as a self-adhesive film. In this case, the first side 301, facing toward the upper side 101 of the lead frame 100, of the second film 300 is configured to be self-adhesive. The self-adhesive first side 301 of the second film 300 in this case adheres to the upper side 101 of the lead frame 100 so that reliable covering of the upper side 101 of the lead frame 100 with the second film 300 can be achieved.

If the second film 300 is not configured as a self-adhesive film, then the second film 300 is preferably configured to be soft and flexible so that reliable covering of the entire upper side 101 of the lead frame 100 with the second film 300 can be achieved by pressing the lead frame 100 onto the first side 301 of the second film 300 except in the uncovered section 310 of the upper side 101 of the lead frame 100.

As an alternative to the procedure described, it is possible to provide the uncovered section 310 not on the upper side 301 of the lead frame 100, but on the lower side 102 of the lead frame 100. In this case, the first film 200 is arranged on the lower side 102 of the lead frame 100 such that it covers all the elevated sections of the lower side 102 of the lead frame 100 except for the uncovered section 310. The second film 300 is arranged on the upper side 101 of the lead frame 100 such that it covers all the elevated sections of the upper side 101 of the lead frame 100.

It is likewise possible to omit the uncovered section 310. In this case, the two films 200, 300 cover all the elevated sections of the upper side 101 and of the lower side 102 of the lead frame 100.

Optionally, of course, the second film 300 may already be arranged on the lead frame 100 before the first film 200.

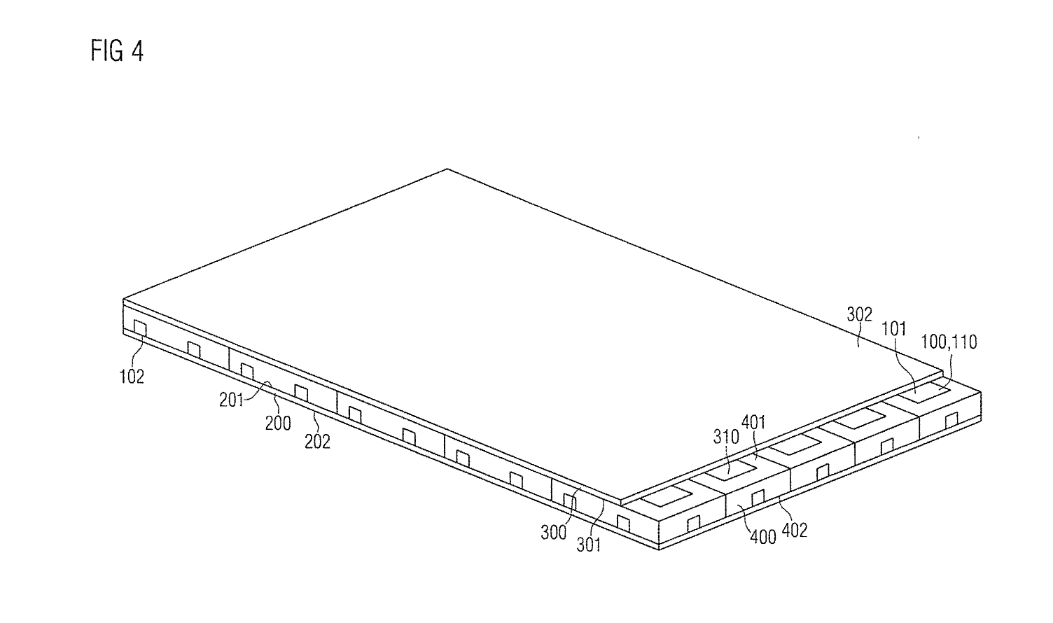

FIG. 4 shows a schematic representation of the lead frame 100 arranged between the films 200, 300 in a processing step chronologically following the representation of FIG. 3.

A molded body 400 has been formed between the first film 200 and the second film 300. The lead frame 100 has been embedded in the molded body 400. The molded body 400 has been formed from an electrically insulating molding material. The molding material may, for example, comprise an epoxy resin and/or a silicone. The molded body 400 has been formed by a molding method, for example, by transfer molding. In this case, the molding material has been introduced into the region between the first film 200 and the second film 300 via the uncovered section 310. As an alternative, the molding material may have been introduced into the region between the first film 200 and the second film 300 from a side flank of the lead frame 100.

The molded body 400 has been formed with an upper side 401 and a lower side 402 lying opposite the upper side 401. The upper side 401 of the molded body 400 has been formed adjacent to the first side 301 of the second film 300. The lower side 402 of the molded body 400 has been formed adjacent to the first side 201 of the first film 200.

The upper side 101 of the lead frame 100, which is protected by the second film 300, and the lower side 102 of the lead frame 100, which is protected by the first film 200, have essentially not been covered with the material of the molded body 400 during the formation of the molded body 400. The upper side 101 of the lead frame 100 is therefore exposed on the upper side 401 of the molded body 400, and terminates essentially flush with the upper side 401 of the molded body 400. Correspondingly, the lower side 102 of the lead frame 100 is exposed on the lower side 402 of the molded body 400, and terminates essentially flush with the lower side 402 of the molded body 400.

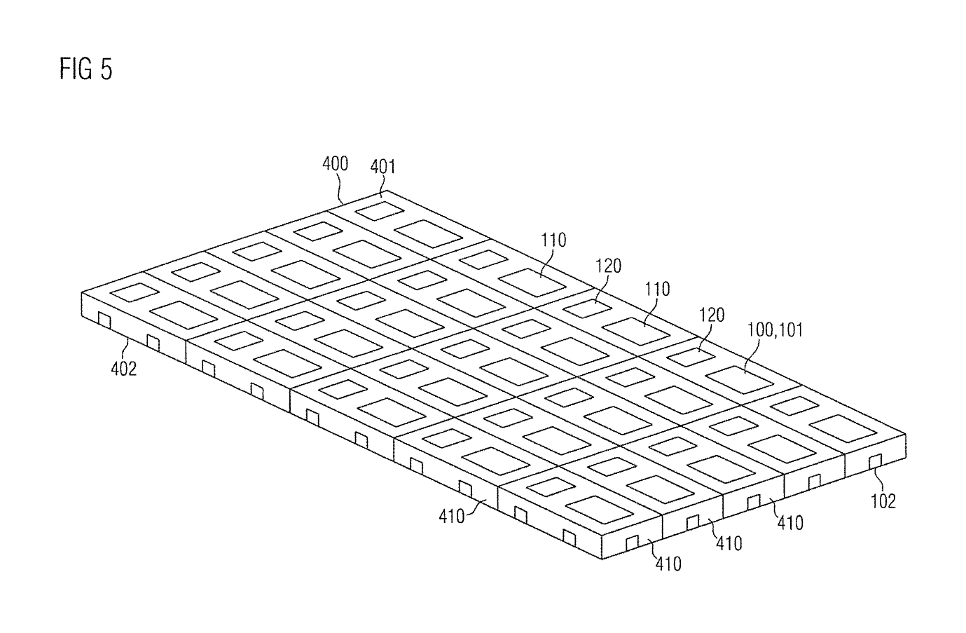

FIG. 5 shows a schematic perspective representation of the molded body 400 in a processing state chronologically following the representation of FIG. 4.

The first film 200 has been removed from the lower side 402 of the molded body 400. Furthermore, the second film 300 has been removed from the upper side 401 of the molded body 400. The removal of the first film 200 and of the second film 300 from the molded body 400 may, for example, have been carried out by mechanical retraction of the films 200, 300.

The molded body 400, with the lead frame 100 embedded in the molded body 400, comprises a multiplicity of molded body sections 410 connected continuously to one another in one piece. A first lead frame section 110 and an associated second lead frame section 120 of the lead frame 100 are embedded in each molded body section 410 of the molded body 400. The individual molded body sections 410 may be individualized by dividing the molded body 400 and the lead frame 100 embedded in the molded body 400. Division of the molded body 400 and of the lead frame 100 embedded in the molded body 400 may, for example, be carried out by a sawing process.

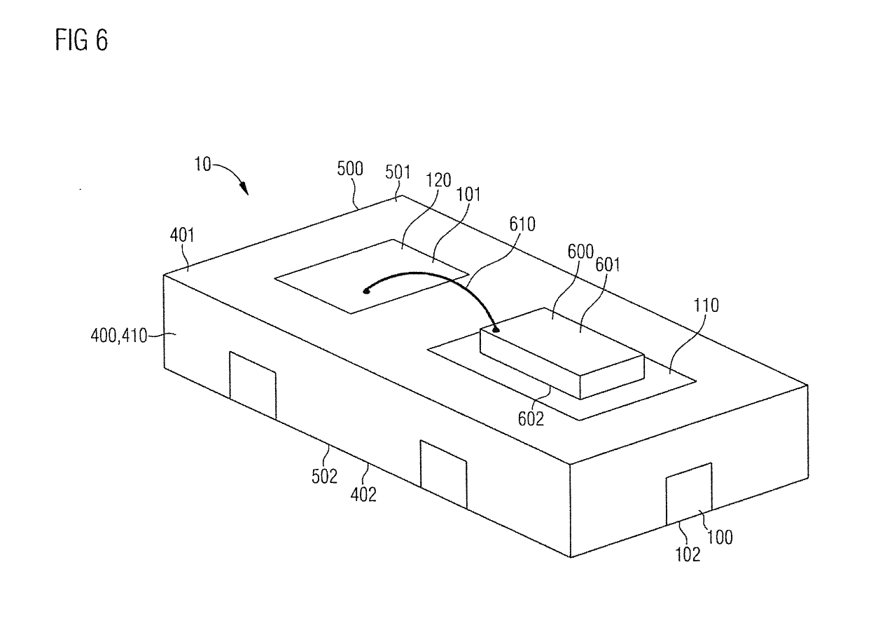

FIG. 6 shows a schematic perspective representation of an optoelectronic component 10.

The optoelectronic component 10 comprises an individualized molded body section 410 of the molded body 400 of FIG. 5, which forms a carrier 500 of the optoelectronic component 10. The upper side 401 of the molded body section 410 forms an upper side 501 of the carrier. The lower side 402 of the molded body section 410 forms a lower side 502 of the carrier 500.

One of the first lead frame sections 110 and one of the second lead frame sections 120 of the lead frame 100 are embedded in the molded body section 410 forming the carrier 500. The first lead frame section 110 embedded in the molded body section 410 forming the carrier 500 is electrically insulated from the second lead frame section 120 embedded in the molded body section 410. The first lead frame section 110 and the second lead frame section 120 are accessible both on the upper side 501 and on the lower side 502 of the carrier.

An optoelectronic semiconductor chip 600 is arranged on the upper side 501 of the carrier 500 of the optoelectronic component 10. The optoelectronic semiconductor chip 600 may, for example, be a light-emitting diode chip (LED chip). The optoelectronic semiconductor chip 600 has an upper side 601 and a lower side 602 lying opposite the upper side 601. The optoelectronic semiconductor chip 600 is arranged on the upper side 501 of the carrier 500 such that the lower side 602 of the optoelectronic semiconductor chip 600 faces toward the upper side 501 of the carrier 500. The optoelectronic semiconductor chip 600 may, for example, be fastened on the upper side 501 of the carrier 500 by a solder connection or an adhesive bond.

The optoelectronic semiconductor chip 600 electrically conductively connects to the first lead frame section 110 and the second lead frame section 120 of the carrier 500 of the optoelectronic component 10. In the example represented in FIG. 6, the optoelectronic semiconductor chip 600 is arranged on the first lead frame section 110 so that there is an electrically conductive connection between an electrical contact of the optoelectronic semiconductor chip 600, arranged on the lower side 602 of the optoelectronic semiconductor chip 600, and the first lead frame section 110 of the carrier 500. A second electrical contact of the optoelectronic semiconductor chip 600, arranged on the upper side 601 of the optoelectronic semiconductor chip 600, electrically conductively connects to the second lead frame section 120 by a bonding wire.

It is, however, also possible to produce the electrically conductive connection between the optoelectronic semiconductor chip 600 and the first lead frame section 110, for example, by a bonding wire. In this case, the two electrical contacts of the optoelectronic semiconductor chip 600 may be arranged on its upper side 601.

It is likewise possible to provide the two electrical contacts of the optoelectronic semiconductor chip 600 on its lower side 602, and to arrange the optoelectronic semiconductor chip 600 in the manner of a bridge on the first lead frame section 110 and the second lead frame section 120 of the carrier 500 such that there are electrically conductive connections between the electrical contacts of the optoelectronic semiconductor chip 600 and the lead frame sections 110, 120 of the carrier 500.

Arrangement of the optoelectronic semiconductor chip 600 on the upper side 501 of the carrier 500 formed by the molded body section 410 of the molded body 400 is preferably already carried out before the division of the molded body 400 into the individual molded body sections 410. In this case, one optoelectronic semiconductor chip 600 is respectively arranged on each molded body section 410 of the molded body 400 and electrically conductively connected to the first lead frame section 110 and the second lead frame section 120 of the respective molded body section 410. Only then is the molded body 400 divided into the individual molded body sections 410. In this way, a multiplicity of optoelectronic components 10 are simultaneously formed. As an alternative, however, it is also possible not to arrange the optoelectronic semiconductor chip 600 on the upper side 501 of the carrier 500 formed by a molded body section 410 until after the division of the molded body 400.

The sections of the first lead frame section 110 and the second lead frame section 120 exposed on the lower side 502 of the carrier 500 of the optoelectronic component 10 may form electrical contact pads of the optoelectronic component 10 and be used for electrical contacting of the optoelectronic component 10. The optoelectronic component 10 may, for example, be provided as an SMT component for surface mounting, for example, for surface mounting by reflow soldering.

My methods have been illustrated and described in detail with the aid of preferred examples. This disclosure is not, however, restricted to the examples disclosed. Rather, other variants may be derived therefrom by those skilled in the art without departing from the protective scope of the appended claims.

This application claims priority of DE 10 2014 116 370.2, the subject matter of which is incorporated herein by reference.

1-11. (canceled)

12. A method of producing a carrier for an optoelectronic component comprising:
providing a lead frame having an upper side and a lower side;
arranging a first film on the lower side of the lead frame;
arranging a second film on the upper side of the lead frame;
forming a molded body from a molding material, the lead frame being embedded in the molded body; and
removing the first film and the second film.

13. The method according to claim 12, wherein at least one of the first film and the second film are self-adhesive films.

14. The method according to claim 12, wherein at least one of the first film and the second film comprise a polyimide, ETFE or PET.

15. The method according to claim 12, wherein the molded body is formed by a molding method or transfer molding.

16. The method according to claim 12, wherein the first film or the second film is arranged such that a section of the lower side or of the upper side of the lead frame remains uncovered by the film, the molding material being delivered between the first film and the second film at the uncovered section.

17. The method according to claim 12, wherein the molding material comprises at least one of an epoxy resin and a silicone.

18. The method according to claim 12, wherein the lead frame comprises a multiplicity of first lead frame sections and a multiplicity of second lead frame sections.

19. A method of producing an optoelectronic component comprising:
producing a carrier by the method according to claim 12; and
arranging an optoelectronic semiconductor chip on an upper side of the carrier.

20. The method according to claim 19, wherein the optoelectronic semiconductor chip electrically conductively connects to a first lead frame section and a second lead frame section.

21. The method according to claim 20, wherein the optoelectronic semiconductor chip is arranged on a first lead frame section.

22. The method according to claim 20, further comprising:
dividing the molded body to form a molded body section in which one of the first lead frame sections and one of the second lead frame sections are embedded, and
the optoelectronic semiconductor chip is arranged on the molded body section.
